(19) United States
(12) Patent Application Publication
(10) Pub. No.: US 2007/0210701 A1
(43) Pub. Date: Sep. 13, 2007

(54) Dual Screen Organic Electroluminescent Display

(75) Inventors: Min-Ling Hung, Kanding Township (TW); Chun-Yi Chiu, Taoyuan City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: AU OPTRONICS CORPORATION, Hsinchu (TW)

(21) Appl. No.: 11/533,433

(22) Filed: Sep. 20, 2006

(30) Foreign Application Priority Data
Mar. 10, 2006 (TW) 95108215

(51) Int. Cl. H01J 1/62; H01J 63/04

(52) U.S. Cl. 313/504

(57) ABSTRACT

A dual screen organic electroluminescent display made by encapsulating two organic electroluminescent screens is provided. Every organic electroluminescent display comprises a transparent substrate, an organic electroluminescent unit, and a chip bonding pad. The organic electroluminescent unit is electrically connected to the chip bonding pad, and both the organic electroluminescent unit and the chip bonding pad are located on the same surface of the transparent substrate. The width of a UV encapsulating glue layer, which is located between the organic electroluminescent unit and the chip bonding pad, is between 0.5 to 10 mm.

### RELATED APPLICATIONS

The present application is based on, and claims priority from, Taiwan Application Serial Number 95108215, filed Mar. 10, 2006, the disclosure of which is hereby incorporated by reference herein in its entirety.

### BACKGROUND

1. Field of Invention

The present invention relates to a dual screen organic electroluminescent display. More particularly, the present invention relates to a dual screen organic electroluminescent display that prevents the spillage of encapsulating glue when encapsulating.

2. Description of Related Art

With the advancement and evolution of electronic devices, the reaction speed, the resolution and the definition of displays have improved, and the function and the display modes are more advanced. One of the examples is the gradual increase in the need for the portable electronic devices equipped with dual displays, such as folded cell phones, PDAs and notebooks. Dual screens do not only stretch out the size of a display and widen the view, but it is also helpful to switch screens and deal with more tasks. For portable electronic devices, the light weights and small sizes are most important. Main stream displays of modern portable electronic devices are twisted-nematic LCDs and thin-film transistor LCDs. However, though the LCDs are already a kind of light and thin plane displays, there is still a long way to go when being applied to dual screen displays.

It is obvious that one cannot obtain a light, thin and small dual screen display if he or she assembles one by simply combining two individual LCDs back to back. The modern display industry are paying close attention to organic electroluminescent light emitting diode (OLED) displays because of their ability to emit light without back light modules, light weights, small sizes, simple structures, robustness and low costs. Therefore dual screen organic electroluminescent displays are becoming important in the development of dual screen displays.

Reference is now made to FIG. 1. FIG. 1 illustrates a sectional view of a prior art dual screen organic electroluminescent display. The organic electroluminescent screens 100 and 102 are initially encapsulated separately, and are reassembled back together afterwards. The arrows 104 and 106 in FIG. 1 represent the directions of light emitted by the organic electroluminescent screens 100 and 102 respectively. Since the aforementioned dual screen organic electroluminescent display needs to encapsulate the organic electroluminescent screens individually and then assemble them together, both the cost and the space are twice as high and large as that of the single screen organic electroluminescent display, which is obviously a drawback for electronic devices.

FIG. 2 is a sectional view of another prior art dual screen organic electroluminescent display. The organic electroluminescent screens 200 and 202 are stuck and encapsulated by an encapsulating glue layer 204. The encapsulating glue layer 204 encapsulates the organic electroluminescent screens 200 and 202 in order to prevent water vapor from entering the panel light emitting area. Usually, the encapsulating glue layer 204 is made of UV encapsulating glue. In the encapsulating process, water vapor may not be prevented completely if the amount of encapsulating glue is insuffucient. Water vapor reduces the life of the organic electroluminescent screen. However, if the amount of encapsulating glue is too much, the glue may spill. The spilled encapsulated glue may come into contact with components in the light emitting area and break those components. It is also possible that the spilled encapsulated glue comes into contact with the chip bonding pads and the chip bonding pads may fail to electrically connect to the conducting lines well. It is still possible that the encapsulating glue may spill to the scribing area such that the scribing process cannot be executed.

For the forgoing reasons, there is a need for a dual screen organic electroluminescent display that is not made by simply assembling two organic electroluminescent screens back to back and avoids the problem of spilling encapsulating glue.

### SUMMARY

The present invention is directed to a dual screen organic electroluminescent display that integrates and encapsulates organic electroluminescent diode display units into a dual screen organic electroluminescent display. By means of the integrated encapsulation structure, the weight and the size of the dual screen organic electroluminescent screen can be reduced. Furthermore, the encapsulation process can be accomplished at once, which is helpful to decrease the cost.

The dual screen organic electroluminescent display of the present invention is formed by integrating and encapsulating two bottom-luminescence organic electroluminescent screens together. Each of the two bottom-luminescence organic electroluminescent screens includes a transparent substrate, a plurality of organic electroluminescent units and an insulation layer. The two bottom-luminescence organic electroluminescent screens are staggered in order to expose the chip bonding pads to ensure successful chip bonding. The organic electroluminescent units are formed over a surface of the transparent substrates. The organic electroluminescent unit is a pile of a transparent electrode, an organic electroluminescent layer, and an upper electrode, wherein the transparent electrode and the upper electrode are installed on two different sides of the organic electroluminescent layer respectively in order to utilize the external voltage to emit the light. The transparent substrate is chosen from a category composed of glass substrates and plastic substrates, the upper electrode may be a metal electrode, and the transparent electrode is chosen from a category composed of Indium tin oxide (ITO), Indium zinc oxide (IZO) and a thin metal layer. The organic electroluminescent layer includes a combination of a hole injection layer, a hole conduction layer, an organic electroluminescent material layer, an electron transfer layer, an electron injection layer, and a carrier production layer.

Besides, there is a further insulation layer on the metal electrode, covering the organic electroluminescent unit. The two bottom-luminescence organic electroluminescent screens are encapsulated, the insulation layer-to-the insulation layer, into a dual screen organic electroluminescent display. The dual screen organic electroluminescent display further includes one or more hygroscopic material layers encapsulated between the two transparent substrates.

Comparing the present dual screen organic electroluminescent display to the conventional laminated dual screen organic electroluminescent display, the components such as the cover glass can be saved to reduce the cost. The UV encapsulating glue is utilized for encapsulation. The width of the encapsulating glue coated on the substrate is smaller than the width between the edge of the light emitting area and the edge of the chip bonding pad area. The width of the encapsulating glue is preferably between 0.5 to 10 mm.

The organic electroluminescent screens of the present invention are driven by a passive matrix or an active matrix, or driven in a mode combining a passive matrix and an active matrix. Further, the dual screen organic electroluminescent display of the present invention may be applied in a monochrome display mode, a high color display mode and a true color display mode. The organic electroluminescent display of the present invention also includes the polymer light emitting diode (PLED) display.

These and other features, aspects, and advantages of the present invention will become better understood with reference to the following description, figures, and appended claims.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a sectional view of a prior art dual screen organic electroluminescent display,

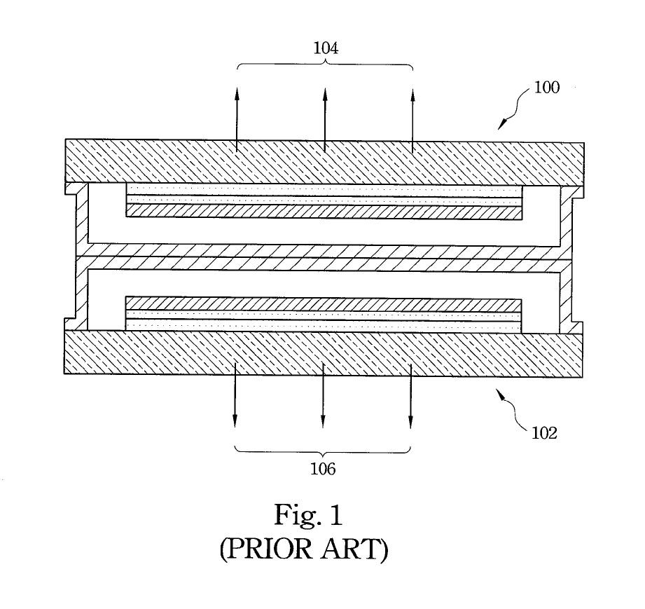

FIG. 2 is a sectional view of another prior art dual screen organic electroluminescent display,

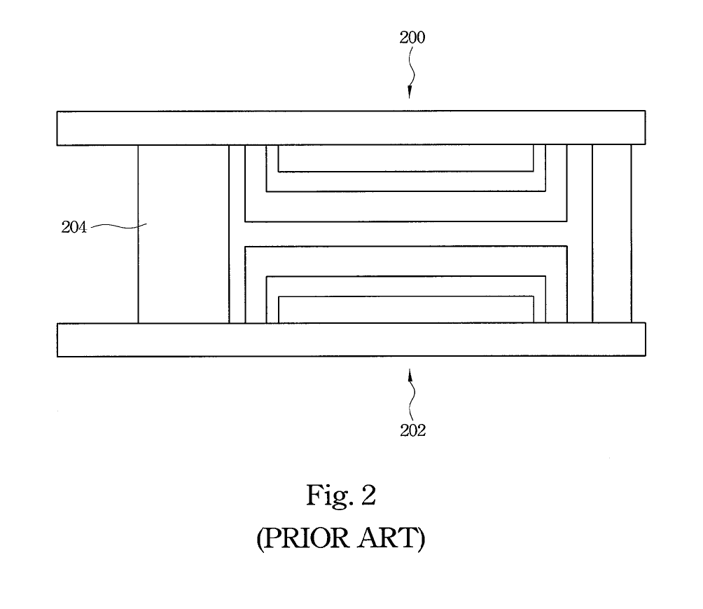

FIG. 3 is a sectional view of a dual screen organic electroluminescent display according to a preferred embodiment of the present invention, and

FIG. 4 is a front view of the dual screen organic electroluminescent display illustrated in FIG. 3.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

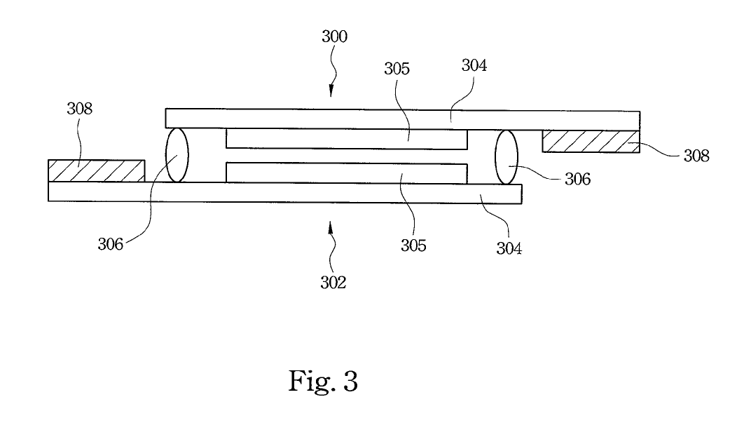

Please refer to FIG. 3. A sectional view of a dual screen organice electroluminescent display is illustrated in FIG. 3 according to one preferred embodiment of the present invention. Two organic electroluminescent screens 300 and 302 are stuck and encapsulated by the encapsulating glue layer 306. Each of the organic electroluminescent screens includes a transparent substrate 304, and an array 305 composed of a plurality of organic electroluminescent units. The organic electroluminescent units are formed upon a surface of the transparent substrate 304. Each organic electroluminescent unit includes a pile of a transparent electrode, an organic electroluminescent layer, and an upper electrode (not shown). The transparent electrode and the upper electrodes are installed on different sides of the organic electroluminescent layer such that the external voltage may be utilized to emit light. The transparent substrate 304 is chosen from a category composed of glass substrates and plastic substrates. For the upper electrode, it may be a metal electrode. The transparent electrode is chosen from a category composed of Indium tin oxide (ITO) layers, an Indium zinc oxide (IZO) layers and thin metal layers; while the organic electroluminescent layer includes a combination of a hole injection layer, a hole conduction layer, an organic electroluminescent material layer, an electron transfer layer, an electron injection layer, and a carrier production layer (not shown).

Besides, there is an insulation layer (not shown) above the metal electrode, covering the organic electroluminescent unit. The two bottom-luminescence organic electroluminescent display panels 300 and 302 are disposed using insulation layers aligned in the insulation layer direction and encapsulated to form the dual organic electroluminsecent display. Afterwards, the two bottom-luminescence organic electroluminescent display panels 300 and 302 are assembled into a dual screen organic electroluminescent display accordingly. The dual screen organic electroluminescent display further includes one or more hygroscopic material layers (not shown) encapsulated between the two transparent substrates in order to absorb water vapor permeated into the organic electroluminescent screens.

Please refer to FIG. 3 again. The organic electroluminescent display panel 300 and 302 are staggered and encapsulated by the encapsulating glue layer 306. Hence the chip bonding pad area 308, located at the same side of the transparent substrate 304 as the organic electroluminescent unit array 305 can be exposed accordingly. Therefore the chip bonding pad area 308 can be directly formed upon the transparent substrate 304, which is an advantage of the following process of chip bonding and makes it possible to solder the chip directly onto the transparent substrate 304.

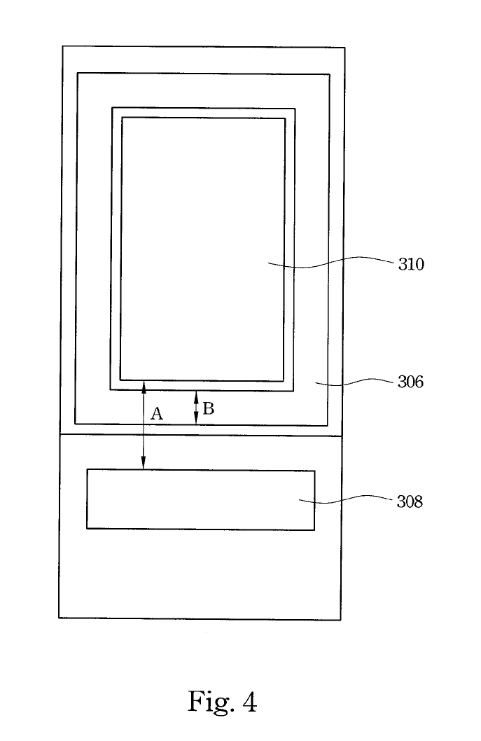

Please refer to FIG. 4. FIG. 4 illustrates a front view of the dual screen organic electroluminescent display shown in FIG. 3. In FIG. 3, the array 305, composed of a plurality of organic electroluminescent units, forms the light emitting area 310. The encapsulating glue layer 306 is coated around the light emitting area 310. As is seen in FIG. 4, the width B of the encapsulating glue layer 306 is narrower than the width A between the edge of the light emitting area 310 and the edge of the chip bonding pad area 308. The range of the width of the encapsulating glue layer 306 is preferably within 0.5 to 10 mm.

According to the preferred embodiment described above, the present invention has the following advantages. The spillage of the encapsulating glue and hence the damage of the components in the light emitting area, the failure of the chip bonding pads, or the incapability of scribing can all be prevented and avoided if the width of the encapsulating glue layer is limited to between 0.5 to 10 mm. Besides, the two organic electroluminescent screens are stuck and encapsulated in a staggered way. Therefore, the chip bonding pads can be directly formed over the transparent substrate, and the chips can be soldered on the transparent substrate directly as well. Accordingly, the complexity of the fabrication process of the dual screen organic electroluminescent display is reduced.

Although the present invention has been described in considerable detail with reference to certain preferred embodiments thereof, other embodiments are possible. Therefore, the spirit and scope of the appended claims should no be limited to the description of the preferred embodiments contained herein.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A dual screen organic electroluminescent display, comprising at least:
two organic electroluminescent screens, wherein each of the two organic electroluminescent screens comprises:
a transparent substrate;
an organic electroluminescent unit, located over a surface of the transparent substrate; and
a chip bonding pad, located at a side of the organic electroluminescent unit and electrically connected to the organic electroluminescent unit; and
an encapsulating layer, surrounding the two organic electroluminescent units for encapsulating the two organic electroluminescent screens with the two organic electroluminescent units opposite to each other, and exposing the two chip bonding pads;
wherein the width of the encapsulating layer, located between the organic electroluminescent unit and the chip bonding pad, lies between 0.5˜10 mm.

2. The dual screen organic electroluminescent display of claim 1, wherein the two organic electroluminescent screens are staggered in order to expose the chip bonding pads.

3. The dual screen organic electroluminescent display of claim 2, wherein the transparent substrate is chosen from a category composed of glass substrates and plastic substrates.

4. The dual screen organic electroluminescent display of claim 3, wherein the organic electroluminescent unit comprises a pile of a transparent electrode, an organic electroluminescent layer, and an upper electrode.

5. The dual screen organic electroluminescent display of claim 4, wherein the transparent electrode is chosen from a category composed of Indium tin oxide (ITO) layers, Indium zinc oxide (IZO) layers and thin metal layers.

6. The dual screen organic electroluminescent display of claim 5, wherein the organic electroluminescent layer comprises a combination of a hole injection layer, a hole conduction layer, an organic electroluminescent material layer, an electron transfer layer, an electron injection layer, and a carrier production layer.

7. The dual screen organic electroluminescent display of claim 6, further comprising an insulation layer covering the organic electroluminescent unit.

8. The dual screen organic electroluminescent display of claim 7, further comprising one or more hygroscopic material layers encapsulated between the two transparent substrates.

9. The dual screen organic electroluminescent display of claim 8, wherein the organic electroluminescent screens are either passive matrix driven or active matrix driven.
